(19) United States
(12) Patent Application Publication
(10) Pub. No.: US 2009/0321901 A1
(43) Pub. Date: Dec. 31, 2009

(54) THERMALLY BALANCED HEAT SINKS

(75) Inventors: Chris Lopez, Phoenix, AZ (US); Brian L. Hahn, Gilbert, AZ (US); Sudhir Kumar, Hillsboro, OR (US); Trevor J. Moody, Phoenix, AZ (US)

Correspondence Address: MARGER JOHNSON & MCCOLLOM, P.C., 210 SW MORRISON STREET, SUITE 400, PORTLAND, OR, 97204, US

(73) Assignee: ANTARES ADVANCED TEST TECHNOLOGIES, INC., Vancouver, WA (US)

(21) Appl. No.: 12/146,384

(22) Filed: Jun. 25, 2008

(51) Int. Cl. H01L 23/495; H01L 21/00

(52) U.S. Cl. 257/675; 438/122; 257/E23.031; 257/E21.001

(57) ABSTRACT

According to example embodiments, a device configured to dissipate heat from a first chip and a second chip on a multi-chip package includes a primary heat sink configured to contact an upper surface of the first chip, a secondary heat sink configured to contact an upper surface of the second chip, the secondary heat sink disposed within the primary heat sink and movable in relation to the primary heat sink, and a thermally conductive substance disposed in contact with the primary heat sink and the secondary heat sink.

### BACKGROUND

When multiple dies or chips are disposed on a single package, it is often necessary to provide a way to effectively dispose of heat that is generated by the dies or chips when the package is operating. One way to do this is by using a single heat sink that contacts upper surfaces of each one of the dies or chips that require thermal dissipation.

While it is a relatively easy task to manufacture a heat sink with a substantially flat surface, it is difficult to ensure that the upper surfaces of the chips or dies that require contact with the heat sink are coplanar. More often than not, slight manufacturing variations from package to package ensures, at best, that the upper surfaces of the dies or chips are merely parallel, with an offset between the upper surfaces that may also vary slightly between packages. This variability makes it difficult to manufacture a single heat sink with a bottom surface that can be placed in contact with the upper surfaces of all the dies or chips without applying excessive pressure to, and potentially destroying, some of the dies or chips.

It is also possible to use a separate heat sink for each one of the dies or chips on the multi-chip package. While this approach can help eliminate the need to manufacture a multi-chip package with coplanar chips, there is also a need to thermally couple the multiple heat sinks. This enables the combined heat dissipating capability of each of the heat sinks to be utilized to cool the chips. Thermal grease, one known type of thermally conductive substance, is also electrically conductive. For this reason, thermal grease is not used to thermally couple multiple heat sinks since the risk of the thermal grease flowing onto one of the chips and shorting is undesirably high. Example embodiments may address these as well as other disadvantages of the related art.

### BRIEF DESCRIPTION OF THE DRAWINGS

FIG. 1 is a perspective view diagram illustrating a primary heatsink according to an example embodiment.

FIG. 2 is another perspective view diagram illustrating the primary heatsink of FIG. 1.

FIG. 3 is a plan view diagram illustrating the primary heatsink of FIG. 1.

FIG. 4 is another plan view diagram illustrating the primary heatsink of FIG. 1.

FIG. 5 is a sectional view diagram illustrating the primary heatsink of FIG. 1.

FIG. 6 is a perspective view diagram illustrating a secondary heatsink according to an example embodiment.

FIG. 7 is another perspective view diagram illustrating the secondary heatsink of FIG. 6.

FIG. 8 is a plan view diagram illustrating the secondary heatsink of FIG. 6.

FIG. 9 is another plan view diagram illustrating the secondary heatsink of FIG. 6.

FIG. 10 is a sectional view diagram illustrating the secondary heatsink of FIG. 6.

FIG. 11 is an elevational view diagram illustrating the secondary heatsink of FIG. 6.

FIG. 12 is a sectional view diagram illustrating a heatsink assembly that includes the secondary heatsink of FIG. 6 and the primary heatsink of FIG. 1.

FIG. 13 is an exploded view diagram illustrating some components of a device in accordance with an example embodiment.

FIGS. 14A and 14B are sectional view diagrams illustrating assembled components of the device of FIG. 13.

FIG. 15 is a flowchart illustrating a method of removing heat from a first chip and a second chip on a multi-chip package according to an example embodiment.

### DETAILED DESCRIPTION OF EXAMPLE EMBODIMENTS

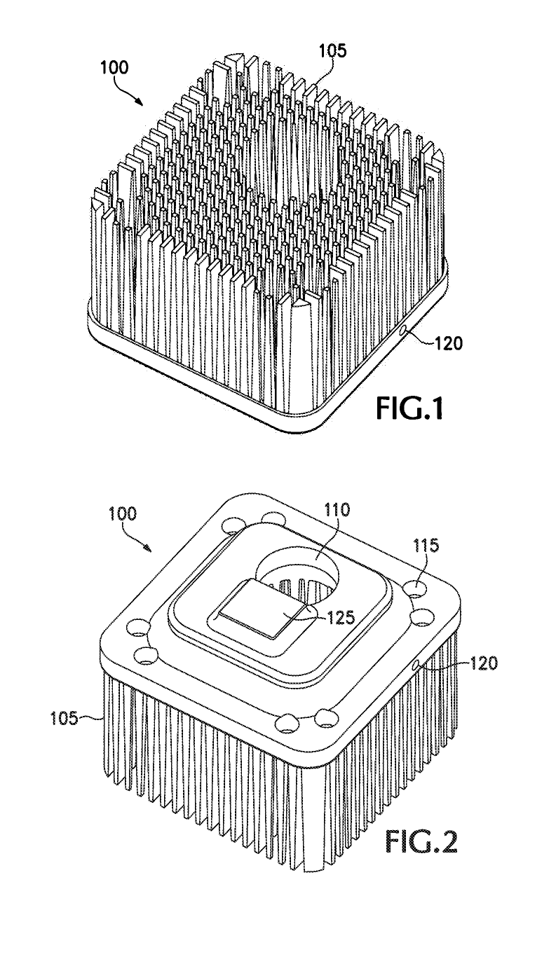

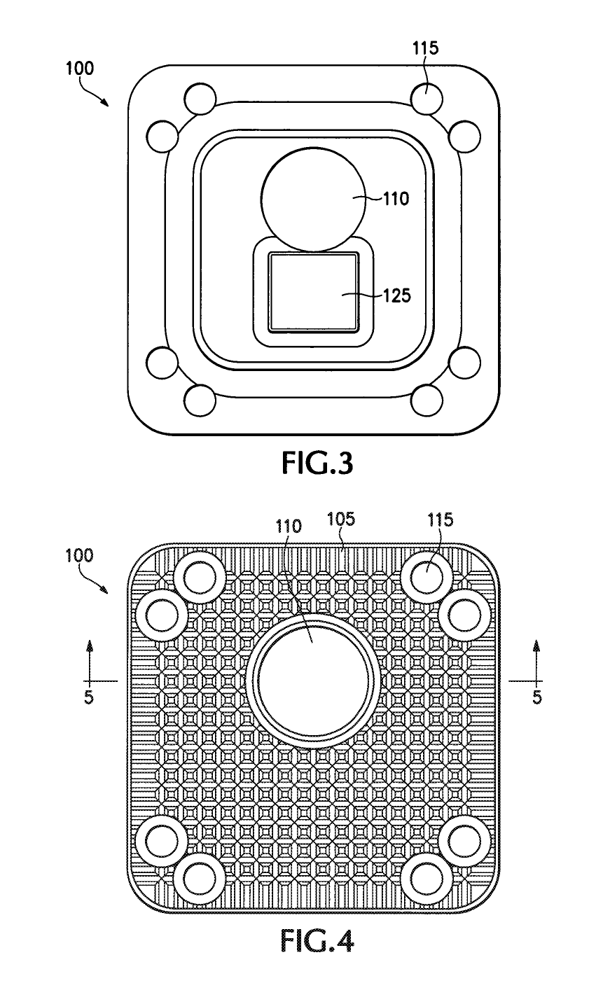

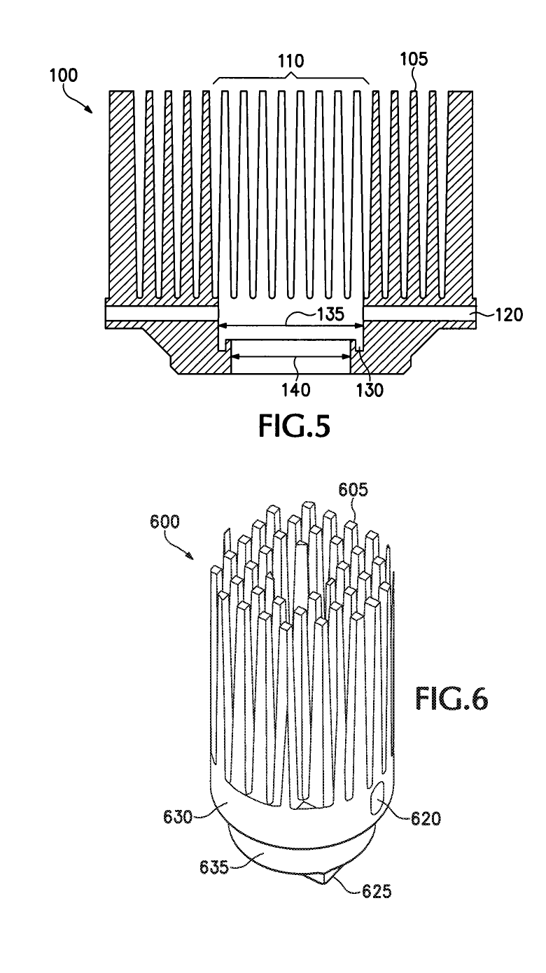

FIG. 1 is a perspective view diagram illustrating a primary heatsink 100 according to an example embodiment. FIG. 2 is another perspective view diagram illustrating the primary heatsink 100 of FIG. 1. FIG. 3 is a plan view diagram illustrating the primary heatsink 100 of FIG. 1. FIG. 4 is another plan view diagram illustrating the primary heatsink 100 of FIG. 1. FIG. 5 is a sectional view diagram illustrating the primary heatsink 100 of FIG. 1. The sectional view diagram of FIG. 5 is taken along the line 5-5 illustrated in FIG. 4.

Referring to FIGS. 1 through 5, the primary heatsink 100 includes a number of fins 105, a cavity 110, fastener holes 115, a dowel hole 120, and a contact surface 125. In this example embodiment, the primary heatsink 100 is a single, integral piece of metal that is cast or machined into the illustrated shape. As will be appreciated, a chip or die (not shown) that is in contact with the contact surface 125 will readily transfer heat to the heatsink 100, where the numerous fins 105 dissipate the heat.

The fastener holes 115 penetrate the primary heatsink 100 completely, and are generally arranged in a direction parallel to the fins 105. The purpose of the fastener holes 115 will be explained in further detail below.

Like the fastener holes 115, the cavity 110 penetrates the primary heatsink 100 completely, and is generally arranged in a direction parallel to the fins 105. As will be explained in further detail below, the cavity 110 is sized to accommodate a secondary heatsink that is disposed within the cavity. While the primary heatsink 100 in this embodiment has but a single cavity 110, other example embodiments may have more than one cavity, and each cavity may be a different size to accommodate secondary heatsinks of varying sizes. The relative position of the cavity 110 or cavities in alternate embodiments will depend upon the placement of the die that is to be contacted by the secondary heatsink that is housed in the cavity.

With reference to FIG. 5, it can be seen that the cavity 110 has a larger diameter 135 in the upper portion of the cavity, where the fins 105 are disposed, compared to a smaller diameter 140 of the cavity that is proximate to the contact surface 125. FIG. 5 also illustrates that the primary heatsink 100 includes a groove 130 that is disposed around the edge of the lower portion of the cavity 110, at the point where the cavity transitions from the larger diameter 135 to the smaller diameter 140. As will be explained in further detail below, the groove 130 of the primary heatsink 100 functions as a grease trap.

The dowel holes 120 of the primary heatsink 100 penetrate the primary heatsink from opposite sides and open into the cavity 110. The dowel holes 120 are aligned with each other so that a single dowel pin (not shown) may be inserted into the dowel holes, forming an obstruction across the cavity 110. As will be explained in further detail below, the dowel pin will serve to retain the secondary heatsink within the cavity 110.

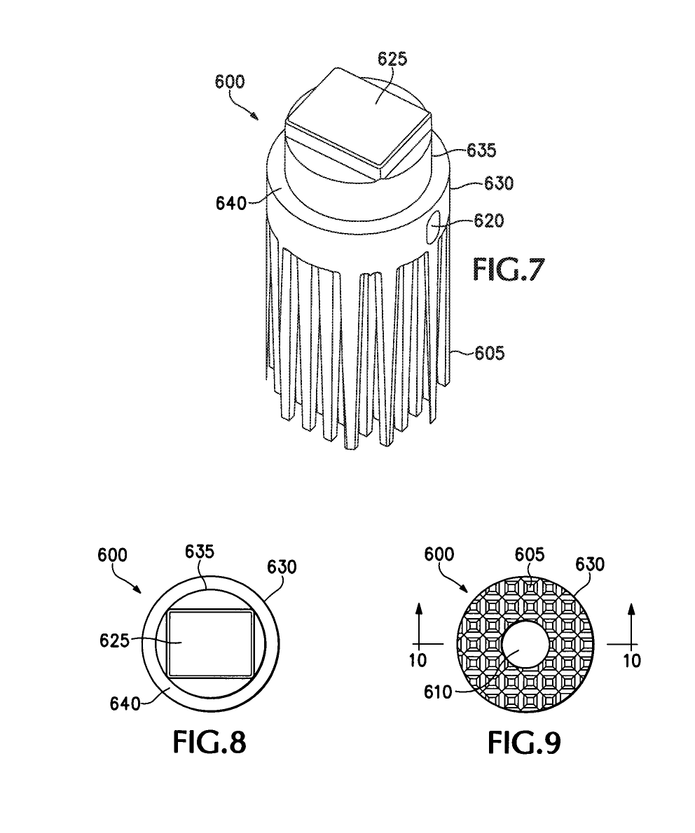

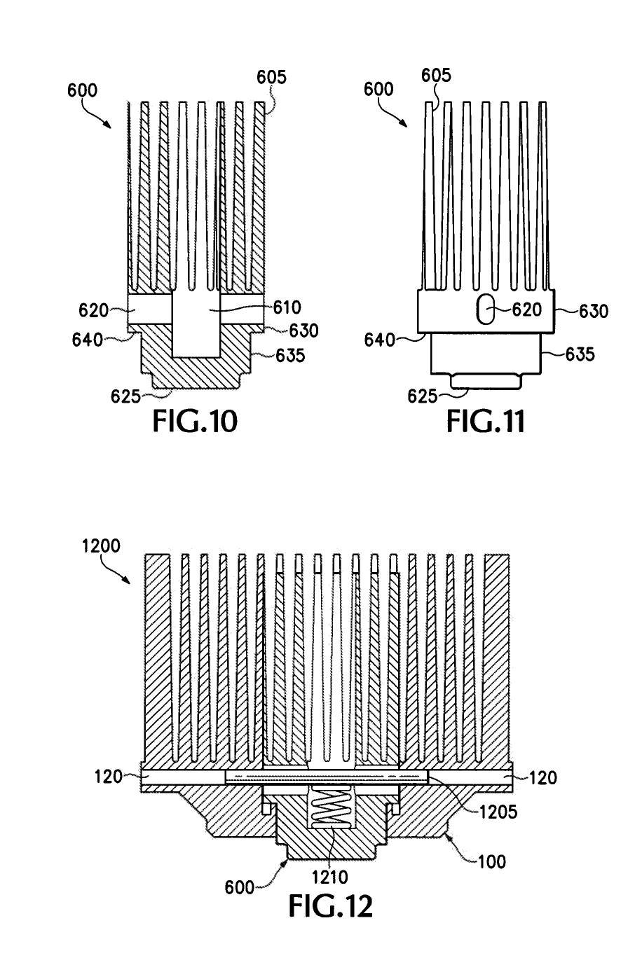

FIG. 6 is a perspective view diagram illustrating a secondary heatsink 600 according to an example embodiment. FIG. 7 is another perspective view diagram illustrating the secondary heatsink 600 of FIG. 6. FIG. 8 is a plan view diagram illustrating the secondary heatsink 600 of FIG. 6. FIG. 9 is another plan view diagram illustrating the secondary heatsink 600 of FIG. 6. FIG. 10 is a sectional view diagram illustrating the secondary heatsink 600 of FIG. 6. The sectional view diagram of FIG. 10 is taken along the line 10-10 of FIG. 9. FIG. 11 is an elevational view diagram illustrating the secondary heatsink 600 of FIG. 6.

Referring to FIGS. 6 through 11, the secondary heatsink 600 includes a number of fins 605, a spring hole 610, dowel holes 620, and a contact surface 625. In this example embodiment, the secondary heatsink 600 is a single, integral piece of metal that is cast or machined into the illustrated shape. The secondary heatsink 600 may or may not be composed of the same material as the primary heatsink 100. It will be appreciated that a chip or die (not shown) that is in contact with the contact surface 625 of the secondary heatsink 600 will readily transfer heat to the secondary heatsink, where the numerous fins 605 dissipate the heat.

The spring hole 610 does not completely penetrate the secondary heatsink 600, and is generally arranged in a direction parallel to the fins 605. The dowel holes 620 of the secondary heatsink 600 penetrate the secondary heatsink from opposite sides and open into the spring hole 610. The dowel holes 620 are aligned with each other so that a single dowel pin (not shown) may be inserted into the dowel holes, forming an obstruction across the spring hole 610. As will be explained in further detail below, the dowel pin will serve to retain the secondary heatsink 600 within the cavity 110 of the primary heatsink 100.

In the illustrated embodiment, the secondary heatsink 600 is generally cylindrical in shape, and has an outer radial edge 630 and an inner radial edge 635. The outer radial edge 630 has a slightly larger diameter than the inner radial edge 635, and forms a shoulder 640 where the outer radial edge transitions to the inner radial edge.

FIG. 12 is a sectional view diagram illustrating a heatsink assembly 1200 that includes the primary heatsink 100 of FIG. 1 and the secondary heatsink 600 of FIG. 6. The sectional view diagram of FIG. 12 is taken along the lines 5-5 of FIGS. 4 and 10-10 of FIG. 9. In the following discussion, many elements of the primary heatsink 100 and the secondary heatsink 600 that were already identified in one or more of FIGS. 1-11 are not identified in FIG. 12 to avoid unnecessarily obscuring the relationship between the primary heatsink 100 and secondary heatsink 600. In other words, in the following discussion it may also be necessary to refer to one of one or more of FIGS. 1-11 for clarification as to what particular element of the primary heatsink 100 and secondary heatsink 600 is being identified.

Referring to FIG. 12, the heatsink assembly 1200 is shown with the secondary heatsink 600 inserted into the cavity 110 of the primary heatsink 100. The outer radial edge 630 of the secondary heatsink 600 is smaller in diameter than the larger diameter 135 of the cavity 110 in the primary heatsink 100. Conversely, the outer radial edge 630 of the secondary heatsink 600 is greater in diameter than the smaller diameter 140 of the cavity 110 in the primary heatsink 100. Thus, when the secondary heatsink 600 is placed within the cavity 110 of the primary heatsink 100 as shown in FIG. 12, the secondary heatsink may move upwards and downwards in the cavity 110.

The extent of downward travel of the secondary heatsink 600 within the cavity 110 is limited where the shoulder 640 of the secondary heatsink meets the bottom of the cavity, at the point where the larger diameter 135 of the cavity transitions to the smaller diameter 140. At this point, the contact surface 625 of the secondary heatsink 600 preferably extends below the contact surface 125 of the primary heatsink 100.

FIG. 12 also illustrates that the heatsink assembly 1200 includes a dowel pin 1205 inserted through the dowel holes 120 of the primary heatsink 100 and the dowel holes 620 of the secondary heatsink 600. When inserted through the dowel holes 120 and 620, the dowel pin 1205 retains the secondary heatsink 600 within the cavity 110 of the primary heatsink 100, preventing the secondary heatsink from being withdrawn from the cavity.

Preferably, even when the dowel pin 1205 is inserted through the dowel holes 120 and dowel holes 620, some relative movement is possible between the secondary heatsink 600 and the primary heatsink 100. As shown in FIG. 12, the height of the dowel holes 620 in the vertical direction is greater than the diameter of the dowel pin 1205. Conversely, the diameter of the dowel holes 120 in the primary heatsink 100 is just slightly larger than the diameter of the dowel pin 1205, thus there is negligible relative vertical movement between the dowel pin 1205 and the primary heatsink 100. The difference between the height of the dowel holes 620 and the diameter of the dowel pin 1205 determines the extent to which the secondary heatsink 600 can move upwards and downwards in the cavity 110 when the dowel pin 1205 is inserted.

In alternative embodiments, the diameter of the dowel holes 620 of the secondary heatsink 600 may be made just slightly larger than the diameter of the dowel pin 1205, while the height of the dowel holes 120 in the primary heatsink 100 may be made greater than the diameter of the dowel pin 1205. In this case, the difference between the height of the dowel holes 120 and the diameter of the dowel pin 1205 would determine the extent of relative vertical movement between the primary heatsink 100 and the secondary heatsink 600. It is also conceivable that both the dowel holes 120 and the dowel holes 620 could be made significantly larger than the diameter of the dowel pin 1205, but this is less preferred as the dowel pin would not be held snugly by at least one set of dowel holes.

The heatsink assembly 1200 illustrated in FIG. 12 also includes a dowel spring 1210, which is inserted into the cavity 110 of the primary heatsink 100 and depressed against the bottom of the cavity prior to inserting the dowel pin 1205 through the dowel holes 120 of the primary heatsink and the dowel holes 620 of the secondary heatsink as was explained above. The dowel spring 1210 exerts a force against the dowel pin 1205 and the bottom of the cavity 110, which forces the secondary heatsink 600 into its lowermost position relative to the primary heatsink 100.

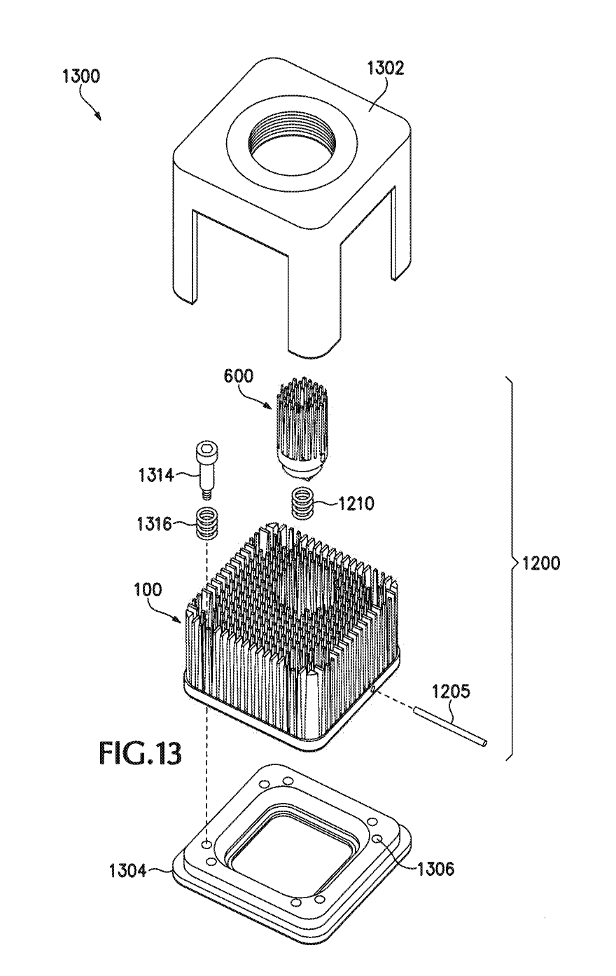

FIG. 13 is an exploded view diagram illustrating some components of a device 1300 in accordance with an example embodiment. The device 1300 includes the heatsink assembly 1200 as illustrated in FIG. 12, a housing 1302, and a platen 1304. Additionally, the device 1300 includes shoulder fasteners 1314 and fastener springs 1316. The lower portions of the shoulder fasteners 1314 are threaded. Only one shoulder fastener 1314 and fastener spring 1314 is illustrated in FIG. 13, but it should be apparent that seven other shoulder fasteners and fastener springs would be required for the other seven fastener holes 115 in the primary heatsink 100 (see FIG. 2).

The platen 1304 includes platen holes 1306 corresponding to each of the fastener holes 115 of the primary heatsink 100. The platen holes 1306 are threaded to accept the threaded lower portion of the shoulder fasteners 1314.

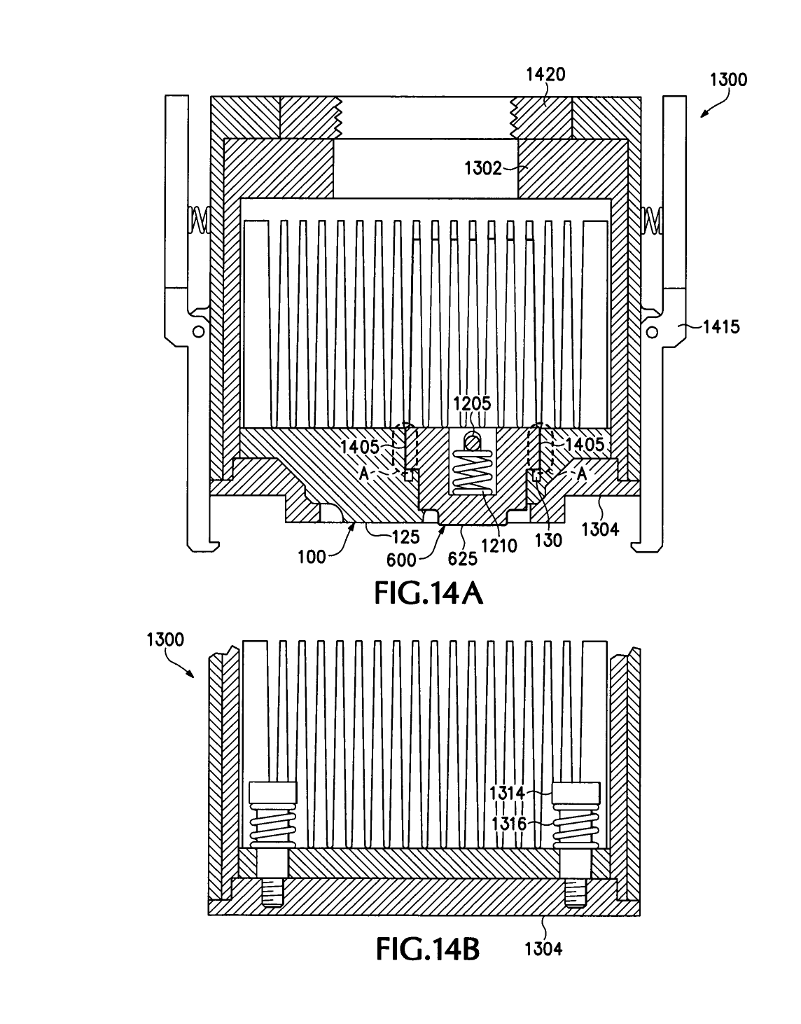

FIGS. 14A and 14B are sectional view diagrams illustrating assembled components of the device 1300 of FIG. 13. In addition to the components that were shown in FIG. 13, FIGS. 14A and 14B additionally illustrate that the device 1300 includes latches 1415 and a thread ring 1420 disposed in the illustrated manner. The latches 1415 are used to connect the device to a device package (not shown) that is being tested. The thread ring 1420 is configured to accept a knob (not shown) having matching threads.

The primary heatsink 100 is secured to the top of the platen 1304 by the shoulder fasteners 1314, which are inserted into the fastener holes 115. The shoulder fasteners 1314 have a threaded bottom portion that can be engaged with the corresponding threaded platen holes 1306 on the top of the platen 1304. The fastener springs 1316, which are also inserted into the fastener holes 115 prior to inserting the shoulder fasteners 1314, are compressed by the shoulder fasteners. Because the fastener springs 1316 are compressed and will naturally try to return to their uncompressed state, the fastener springs exert a downward force against the primary heatsink 100, causing the contact surface 125 of the primary heatsink to be maintained in its lowermost position relative to the platen 1304.

The housing 1302 is arranged to fit over the heatsink assembly 1200 without touching the fins 105 of the primary heatsink 100. The latches 1415 are disposed on the sides of the housing 1302 as shown, and are arranged to latch to the underside of the multi-chip or multi-die package (not shown), which is arranged beneath the device 1300. When the latches 1415 are engaged, the heatsink assembly 1200 is held in place over the multi-chip or multi-die package.

The thread ring 1420 is used in conjunction with a knob (not shown) to apply pressure to the top of the heatsink assembly 1200, which lowers the contact surface 125 of the primary heatsink 100 and the contact surface 625 of the secondary heatsink 600 against the corresponding chips or dies on the multi-chip or multi-die package.

Because the dowel spring 1210 can be compressed even further if necessary, the relative position of the contact surface 625 of the secondary heatsink 600 relative to the contact surface 125 of the primary heatsink 100 is automatically adjusted to account for the variable difference in height of the corresponding chips or dies due to the manufacturing process. Thus, adequate contact between the contact surfaces 125, 625 of the primary and secondary heatsinks 100, 600 and their corresponding chips or dies on the multi-chip or multi-die package is ensured.

Another feature of the device 1300 is visible in FIG. 14A, and that is the groove 130 in the primary heatsink 100. The groove 130 is substantially circular, and is disposed along the bottom peripheral edge of the cavity 110. Of course, in other embodiments the overall shape of the groove may be different in order to match the shape of the cavity and the shape of the corresponding secondary heatsink. For example, a groove disposed along the bottom peripheral edge of a substantially square cavity in the primary heatsink should also be substantially square.

According to the example embodiment, there is additionally a thin layer of thermal grease 1405 disposed in contact with both the primary heatsink 100 and the secondary heatsink 600, in the region above the groove 130 and below the fins 105 and 605, where the substantially vertical surface of the primary heatsink meets the substantially vertical surface of the secondary heatsink. In FIG. 14A this region is indicated by two dashed circles labeled “A,” but it should be understood that this region is continuous along the circular interface between the primary heatsink 100 and the secondary heatsink 600. The thermal grease 1405 encourages heat transfer between the primary heatsink 100 and the secondary heat sink 600. This allows the combined heat dissipating capability of both the primary heatsink 100 and secondary heatsink 600 to be utilized in order to cool the multiple chips.

The device 1300 advantageously mitigates the risk of using electrically conductive thermal grease to thermally couple the primary heatsink 100 to the secondary heatsink 600, because the groove 130 is disposed in such a manner as to prevent thermal grease 1405 that flows down from the substantially vertical surfaces from contaminating the multi-chip or multi-die package. For this reason, the groove 130 may be referred to as a grease trap. Although thermal grease 1405 is preferred, other types of thermally conductive substances having varying degrees of viscosity may also be used, as the groove 130 would be effective in preventing these other substances from contaminating the multi-chip or multi-die package.

In the illustrated embodiment, the groove 130 has a profile that is substantially rectangular in shape, but other embodiments are not so limited. In other example embodiments the profile of the groove 130 may be, for example, substantially square or substantially V-shaped. In alternative embodiments there may also be multiple grooves 130 at substantially the same relative vertical position on the primary heatsink 100, or there may be multiple grooves 130 arranged at different relative vertical positions on the primary heatsink 100. In the latter case, this might require multiple “steps” in the bottom portion of the primary heatsink 100 and corresponding structures in the bottom portion of the secondary heatsink 600. Generally speaking, then, a grease trap according to example embodiments may be any structure on the primary or secondary heatsinks 100, 600 that prevents thermal grease 1405 that thermally couples the primary and secondary heatsinks from flowing downwards and out from among the interfaces between the primary and secondary heatsinks.

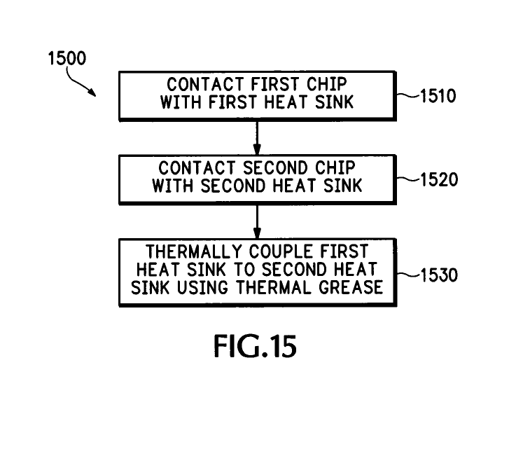

FIG. 15 is a flowchart illustrating some example processes in a method 1500 of removing heat from a first chip and a second chip on a multi-chip package according to an example embodiment. In process 1510, a first chip on the multi-chip package is contacted with a first heat sink. In process 1520, a second chip on the multi-chip package is contacted with a second heat sink. In process 1530, the first heat sink and the second heat sink are thermally coupled using thermal grease. There may be other processes included in the method 1500, and the illustrated processes need not be performed in the order shown.

It should be emphasized that the example embodiments described and illustrated in this disclosure were presented for purposes of illustration, and not for limitation. It will be apparent to those of ordinary skill that various modifications and changes may be made to the example embodiments described without departing from the principles of one or more inventive aspects that exist in all embodiments, as defined in the attached claims.

1. A device configured to dissipate heat from a first chip and a second chip on a multi-chip package, the device comprising:
a primary heat sink configured to contact an upper surface of the first chip;
a secondary heat sink configured to contact an upper surface of the second chip, the secondary heat sink disposed within the primary heat sink and movable in relation to the primary heat sink; and
a thermally conductive substance disposed in contact with the primary heat sink and the secondary heat sink.

2. The device of claim 1, the thermally conductive substance comprising a thermal grease.

3. The device of claim 2, the primary heat sink comprising a grease trap adjacent to a substantially vertical interface between the primary heat sink and the secondary heat sink, the grease trap arranged to prevent the thermal grease from flowing onto an upper surface of the second chip.

4. The device of claim 3, wherein the upper surface of the first chip and the upper surface of the second chip are substantially parallel to each other.

5. The device of claim 4, further comprising:
a spring disposed within the secondary heat sink; and
a dowel pin that is inserted through the primary heat sink and the secondary heat sink, the dowel pin retaining the spring within the secondary heat sink, the dowel pin and spring arranged such that the spring exerts a downward force on the secondary heat sink.

6. The device of claim 5, further comprising:
a platen disposed below the primary heat sink and the secondary heat sink; and
fasteners arranged to attach the primary heat sink to the platen.

7. The device of claim 6, further comprising fastener springs disposed between the fasteners and the primary heat sink, the fastener springs configured to impart to the primary heat sink motion relative to the platen.

8. A method of removing heat from a first chip and a second chip on a multi-chip package, the method comprising:
contacting the first chip with a first heat sink;
contacting the second chip with a second heat sink; and
thermally joining the first heat sink to the second heat sink using a thermal grease in a thermal interface region where the first heat sink abuts the second heat sink.

9. The method of claim 8, further comprising preventing the thermal grease from contacting the first chip and the second chip.

10. The method of claim 9, wherein preventing the thermal grease from contacting the first chip and the second chip comprises configuring the first heat sink to maintain the thermal grease within the thermal interface region.

11. The method of claim 10, wherein contacting the first chip with the primary heat sink comprises contacting an upper surface of the first chip with the primary heat sink, and wherein contacting the second chip with the secondary heat sink comprises contacting an upper surface of the second chip with the secondary heat sink.

12. The method of claim 11, wherein the upper surface of the first chip and the upper surface of the second chip are substantially parallel.

13. The method of claim 12, wherein the upper surface of the first chip and the upper surface of the second chip are not substantially coplanar.

14. The method of claim 13, wherein contacting the upper surface of the second chip with the secondary heat sink comprises forcing the secondary heat sink against the upper surface of the second chip using a spring.

15. A device comprising:
a primary heat sink that includes a cavity that penetrates the primary heat sink along an axis, a center of the cavity substantially aligned with the axis;
a secondary heat sink structured to fit within the cavity, the secondary heat sink capable of movement along the axis when disposed within the cavity; and
a protrusion disposed on the bottom of the cavity, the protrusion extending upwards in a direction substantially parallel to the axis, the protrusion disposed around the center of the cavity and continuous around the center of the cavity.

16. The device of claim 15, further comprising a thermally conductive substance disposed on an interface between the primary heat sink and the secondary heat sink, the interface substantially parallel to the axis, the thermally conductive substance capable of increasing the heat transfer rate between the primary heat sink and the secondary heat sink.

17. The device of claim 16, the thermally conductive substance comprising a grease.

18. The device of claim 17, the protrusion disposed between the interface and the center of the cavity, the protrusion structured to prevent the grease from flowing out of the cavity.

19. The device of claim 18, the primary heat sink comprising a bottom surface and the secondary heat sink comprising a bottom surface, the secondary heat sink movable within the cavity such that the bottom surface of the secondary heat sink is not coplanar with the bottom surface of the primary heat sink.

20. The device of claim 19, the primary heat sink and the secondary heat sink comprising fins that are arranged in a direction substantially parallel to the axis.
